(19) United States
(12) Patent Application Publication
(10) Pub. No.: US 2007/0023228 A1
(43) Pub. Date: Feb. 1, 2007

(54) Multifunction speaker cabinet

(76) Inventor: Yu-Shu Lin, Taoyuan (TW)

Correspondence Address: LOWE HAUPTMAN BERNER, LLP, 1700 DIAGONAL ROAD, SUITE 300, ALEXANDRIA, VA, 22314, US

(21) Appl. No.: 11/191,951

(22) Filed: Jul. 29, 2005

(51) Int. Cl. H05K 5/00; A47B 81/06

(52) U.S. Cl. 181/148; 181/199

(57) ABSTRACT

A multifunction speaker cabinet has a USB input on one side of the speaker cabinet while the USB input is connected with a plurality of USB output exposed on another side of the speaker cabinet so that users can insert several flash into the USB output for connection with the computer main frame. A MP3 audio input is arranged on the speaker cabinet for uses to listen to computer music such as MP3 by an earphone in mute mode or display the music through the speaker cabinet. Moreover, there is a space on the speaker cabinet for accommodating a transparent container with various liquid and ornaments therein. Therefore, besides general function, the speaker cabinet has functions of extension line for hubs, listing computer music in mute mode, displaying music from MP3 walker and decorative effect. Both function and novelty of the speaker cabinet are increased.

### BACKGROUND OF THE INVENTION

The present invention relates to a multifunction speaker cabinet, especially a speaker cabinet with functions of an extension line for computer hubs, listening to computer music with an earphone, displaying music of MP3 walker and decorative effect. Both function and appearance of the speaker cabinet are enhanced.

Generally, desktop computers 3 or notebooks are set on desks while being used, as shown in FIG. 4 & FIG. 5. There is a set of speaker cabinet-a right speaker cabinet and a left speaker cabinet. Due to large volume, the general personal computer main unit 31 is put under the desk, as shown in FIG. 4. A slot of floppy disk or compact disk is set on front side of the computer main unit 31 for convenience of users. A plurality of hub (USB connecting end) including mouse, keyboard, flash or memory card is disposed on read side of the computer main unit 31. Due to the frequent use of the flash or memory card, the USB connector on rear end of the main unit 31 makes user inconvenient. Although there is a USB hub with function of extension line available on the market, it occupies space. Moreover, people like to listen to computer music such as MP3 while using computers. Yet when they want to be quiet, they can't use the earphone instead of the speaker cabinet directly. Furthermore, MP3 walker is quite popular now but it can only be used by connection with the earphone. When users are indoors and would like to play the MP3 music, general speaker cabinets can't be used together with the MP3 walker.

### SUMMARY OF THE INVENTION

It is therefore a primary object of the present invention to provide a multifunctional speaker cabinet that has an USB input on one side (such as rear side) of the speaker cabinet for connection with a computer hub by an USB extension line. The USB input inside the speaker cabinet is connected with a plurality of USB output on another side of the speaker cabinet. Thus users can insert the flash into the USB output for connection with the computer main frame. Therefore, the speaker cabinet set on the desk can also be used as an extension line for hubs.

It is another object of the present invention to provide a multifunctional speaker cabinet that has a MP3 audio input for users to connect the speaker cabinet with the MP3 walker by a cable and turn off a switch of a computer audio input on the speaker cabinet for disconnecting with the computer. Thus the music of MP3 walker is displayed through the speaker cabinet. Or the power of the speaker cabinet is turned off, and the input end of the earphone is inserted into the MP3 audio input so as to listen computer music by the earphone. The speaker cabinet is used in combination with the earphone or the MP3 walker.

It is a further object of the present invention to provide a multifunctional speaker cabinet that is disposed with a transparent container for accommodating various liquid and ornaments so that the speaker cabinet also has a decorative effect.

It is a further object of the present invention to provide a multifunctional speaker cabinet that has one or a plurality of LED (Light-Emitting Diode) devices disposed on peripherals of a transparent container inside the speaker cabinet. When the speaker cabinet is turned on, the LED devices synchronously emit light into the transparent container so as to have colorful and shining effect.

### BRIEF DESCRIPTION OF THE DRAWINGS

FIG. 1 is a perspective view of a left speaker cabinet and a right speaker cabinet of an embodiment according to the present invention;

FIG. 2 is a rear view of the embodiment in FIG. 1;

FIG. 3 is a schematic drawing of the embodiment in FIG. 1 while being used;

FIG. 4 is a schematic drawing of the present invention with a computer main frame under the desk while being used;

FIG. 5 is a schematic drawing of the present invention with a computer main frame on the desk while being used.

### DETAILED DESCRIPTION OF THE PREFERRED EMBODIMENT

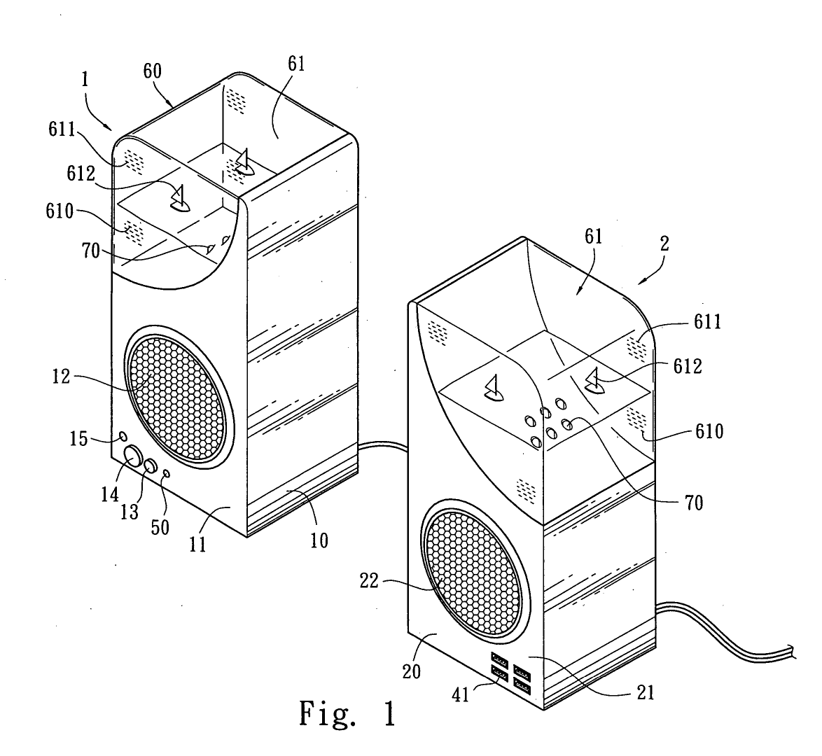

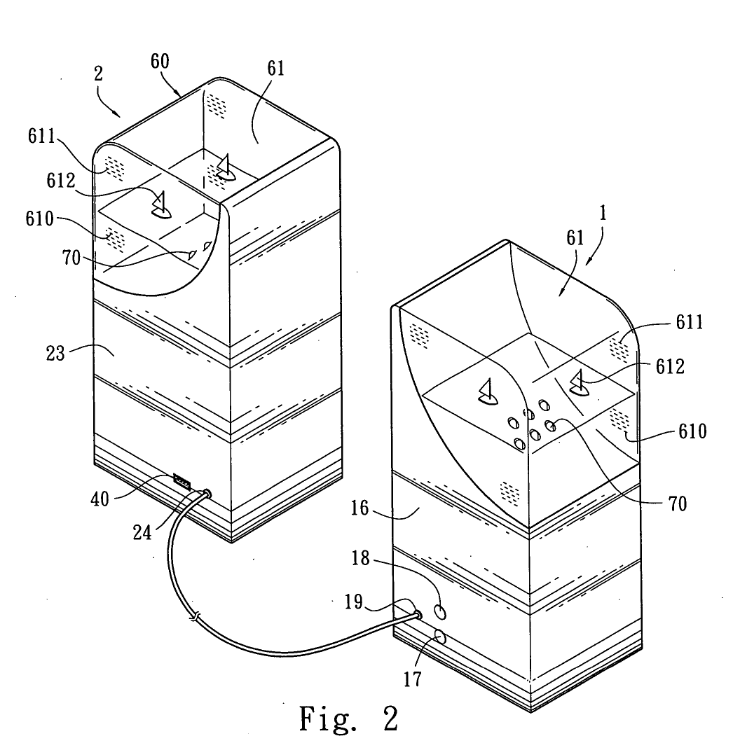

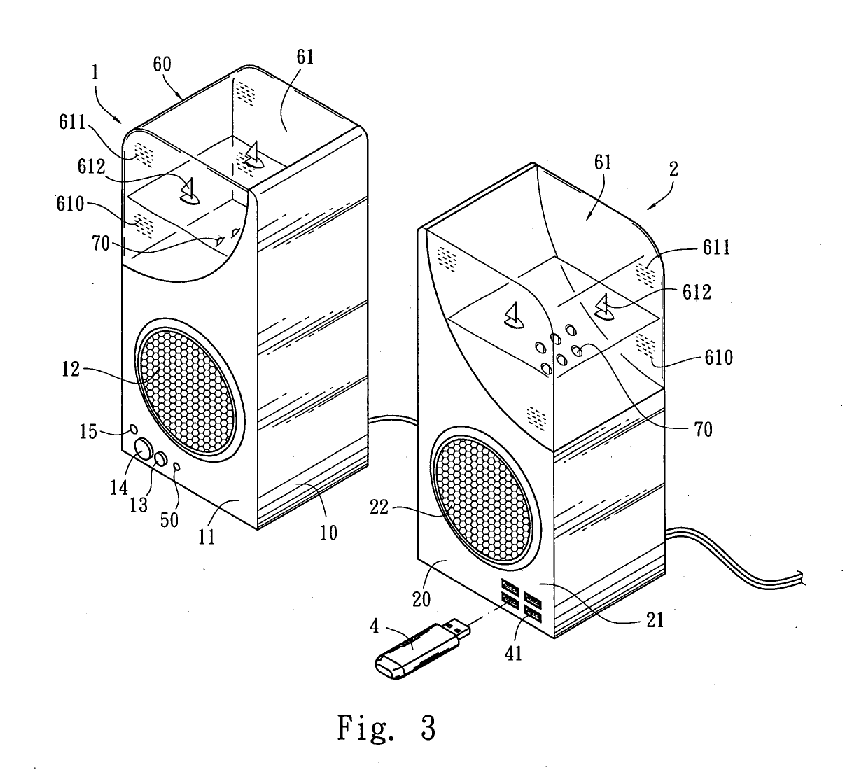

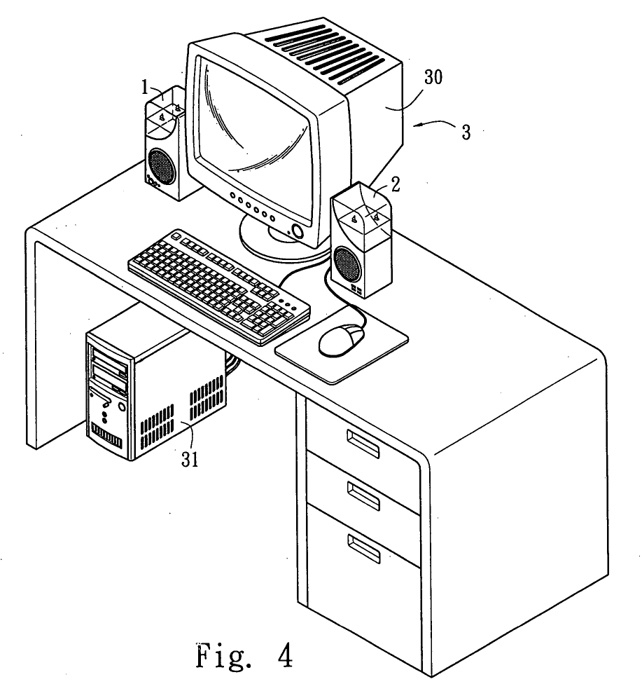

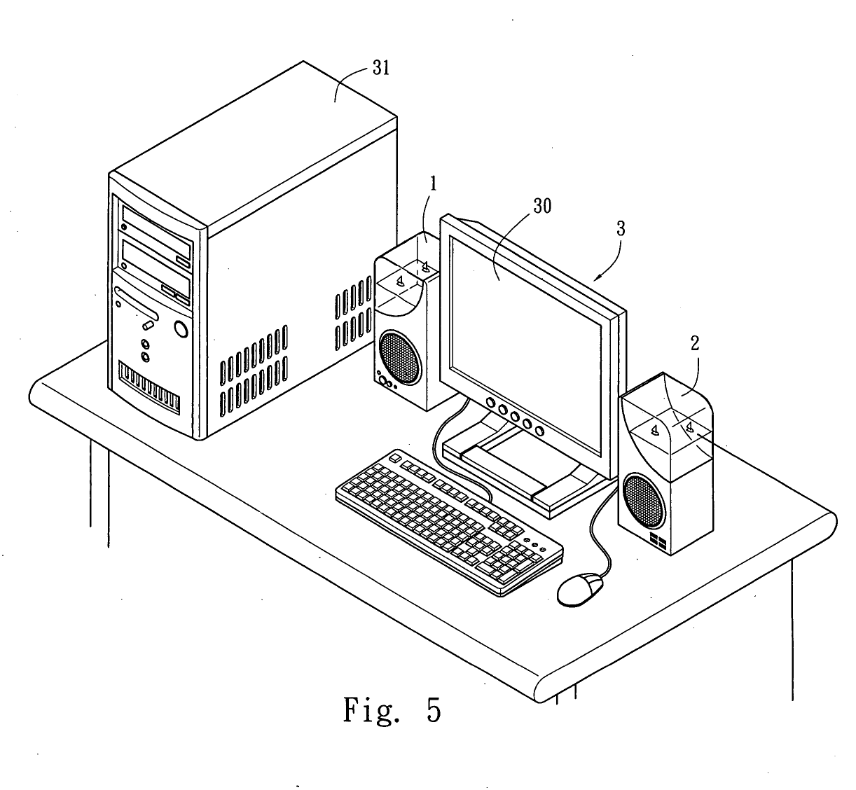

Refer to FIG. 1, FIG. 2 & FIG. 3, a desktop personal computer (PC) 3 (or notebook) put on the desk is used in combination with a set of a left speaker cabinet 1 and a right speaker cabinet 2, as shown in FIG. 4 & FIG. 5. A monitor 30 is disposed on the desk while the main frame 31 is arranged over or under the desk. Each of the speaker cabinets 1,2 includes a housing 10, 20 and electrics are mounted inside the housing 10, 20. The shape of the housings 10, 20 is not limited and is designed for matching appearance of the main frame 31 or the monitor 30. When being used, the speaker cabinets 1,2 can be put on the desk, as shown in FIG. 4 & FIG. 5 or hung on two sides of the monitor 30 (not shown in figure). A speaker hole 12, a power switch 13, a volume button 14, and an indicator lamp 15 are arranged on front side 11 of the left speaker cabinet 1 while a power supply hole 17, audio input for computer 18 and power as well as audio cable for right speaker cabinet 19 for connection with the right speaker cabinet 2 are disposed on rear end 16 thereof. The right speaker cabinet 2 includes a speaker hole 22 on front side 21 and a power supply hole 24 for connecting with the left speaker cabinet 1 on rear side 23 so as to have functions of general speaker cabinets.

The present invention features on that: at least one of the speaker cabinets 1, 2 such as the right speaker cabinet 2, having a USB input 40 on the rear side 23. By an USB extension line (not shown in figure), the USB input 40 is connected with a main hub of the computer main frame 31. Inside the speaker cabinet 2, the USB input 40 connects with several USB output 41 exposed on front side 21 or lateral side of the speaker cabinet 2 so that there are several speaker cabinet 2 on the front side 21. These USB output 41 can be USB slot so that uses can inset the flash 4 into the USB output 41 on the speaker cabinet 2 conveniently, as shown in FIG. 3, connecting with the computer main frame 31 and transmitting information therebetween. Thus refer to FIG. 4 & FIG. 5, when the speaker cabinet 2 is put on the desk, besides general function of the speaker cabinet, it can also used as an extension line of computer hub. While in a prior art, users need to insert the flash into the hub on rear side of the main frame. It's inconvenient and trouble. Moreover, the USB input 40 and the USB output 41 are disposed on either the speaker cabinet 1 or the speaker cabinet 2. Because the speaker cabinet 1 is already mounted with the power switch 13, the volume button 14, the indicator lamp 15 and an audio input for MP3 50, in consideration of inner space of the speaker cabinet, the USB input 40 and the USB output 41 had better be arranged on the speaker cabinet 2.

Another feature of the present invention is that at least one of the left and right speaker cabinets 1, 2 is disposed with an audio input for MP3 50 on the front side 11 thereof. When users don't want to listen the MP3 music by earphones, use a connecting cable to connect an output of earphone with the audio input for MP3 50 and turn off the audio input for computer 18 on the speaker cabinet for disconnecting the MP3 and the computer main frame so that the MP3 music is displayed through the speaker cabinet instead of the earphone to have better audio effect. Moreover, the computer music (including MP3) can be listened by turning off the power switch 13 of the speaker cabinet 1 and inserting the earphone input into the audio input of MP3 50. When the speaker cabinets 1, 2 are used and put on the desk, they are not only used in combination with computers, but also with earphones, or MP3 walker according to user's needs.

A further feature of the present invention is that a transparent container 60 is disposed on the left and the right speaker cabinets 1, 2 respectively. The transparent container 60 is closed or unclosed for accommodating various ornaments. For example, refer from FIG. 1 to FIG. 4, double fluid with floats 61 are arranged inside the transparent container 60. The double fluid with floats 61 consists of fluid with higher density 610 on lower layer, fluid with lower density 611 on upper layer, and floats 612 between the upper and lower layer of liquid. The double fluid with floats 61 is a prior art. When the speaker cabinets 1,2 are put on desk for usage, the ornaments inside the transparent container 60 make the speaker cabinets 1,2 have decorative effect. There is no limitation on shape of the transparent container 60. Various kind of the transparent container 60 are designed for matching the appearance of the left and right speaker cabinets 1,2. The connection way between the transparent container 60 and the speaker cabinets 1,2 is not restricted, it may be adhesion, locking or mounting.

In addition, one or a plurality of LED lighting devices 70 with various colors is disposed on outer peripheral of the transparent container 60. The LED lighting devices 70 can be set up in advance for working synchronously with the power switch 13, USB input/output 40, 41, or the audio input of MP3 50. Thus when the speaker cabinets 1,2 are used, the LED lighting devices 70 illuminate and emit light into the transparent container 60 to produce colorful shining effect. The illumination pattern of the LED lighting devices 70 is design with varieties such as one or several LED lamps with different colors arranged on the same position or different positions. The LED lamps illuminate at the same time or in sequence-flickering and brightness of the lamps varies according to the control of the volume button 14.

What is claimed is:

1. A multifunctional speaker cabinet comprising a speaker hole, a power switch, a volume button, an indicator lamp, and a computer audio input; the speaker cabinet is characterized in that: a USB input is disposed on one side of the speaker cabinet and is connected with a main hub of a computer main frame by an USB extension line; the USB input inside the speaker cabinet is connected with a plurality of USB output exposed on another side of the speaker cabinet so that the speaker cabinet is disposed with the USB output that is inserted with a flash for connection to the computer main frame.

2. The device as claimed in claim 1, wherein the speaker cabinet can be one speaker cabinet or left and right speaker cabinets.

3. The device as claimed in claim 1, wherein the USB input is arranged on rear end of the speaker cabinet while the USB output is disposed on front side or lateral side of the speaker cabinet.

4. The device as claimed in claim 1, wherein a MP3 audio input is disposed on one side of the speaker cabinet and is connected with an earphone output of a MP3 walker by a connecting cable; the computer audio output of the speaker cabinet is turned off thus the music from the MP3 walker is displayed through the cabinet speaker.

5. The device as claimed in claim 4, wherein by inserting an earphone input into the MP3 audio input on one side of the speaker cabinet and turning off the power switch of the speaker cabinet, the computer music is listened through the earphone in mute mode.

6. The device as claimed in claim 1, wherein the speaker cabinet having a space for accommodating a transparent container that is disposed with ornaments for display.

7. The device as claimed in claim 6, wherein the transparent container is a close container or an unclosed container.

8. The device as claimed in claim 7, wherein the close container accommodates double fluid with floats that includes a fluid with higher density on lower layer, fluid with lower density on upper layer, and floats between the upper and lower layer of liquid therein.

9. The device as claimed in claim 6, wherein LED devices are disposed on peripherals of the transparent container inside speaker cabinet and the LED devices face the transparent device.

10. The device as claimed in claim 9, wherein the LED devices having at least one or a plurality of LED with different colors.
